(19) United States
(12) Patent Application Publication
(10) Pub. No.: US 2025/0298111 A1
(43) Pub. Date: Sep. 25, 2025

(54) Inhomogeneity Correction in Main Magnetic Field of MRI Scanner

(71) Applicant: Siemens Healthineers AG, Forchheim (DE)

(72) Inventors: Marcel Dominik Nickel, Herzogenaurach (DE); Daniel Giese, Erlangen (DE)

(73) Assignee: Siemens Healthineers AG, Forchheim (DE)

(21) Appl. No.: 19/084,895

(22) Filed: Mar. 20, 2025

(30) Foreign Application Priority Data
Mar. 21, 2024 (DE) 10 2024 202 698.0

(51) Int. Cl. G01R 33/565; G01R 33/24; G01R 33/48; G01R 33/56

(52) U.S. Cl. CPC G01R 33/56572; G01R 33/243; G01R 33/4828; G01R 33/5608

(57) ABSTRACT

A method for correcting inhomogeneities in the main magnetic field of an MRI scanner, including: providing a B0 magnetic field map of the main magnetic field of the MRI scanner at least in an imaging area; providing distortion information about a behavior of gradient fields of the MRI scanner at least in the imaging area; correcting the B0 magnetic field map or MRI images based on the distortion information by bringing map points of the B0 magnetic field map into alignment with pixels of MRI images with respect to their positions in the imaging area; and outputting the corrected B0 magnetic field map or the corrected MRI images.

### TECHNICAL FIELD

The disclosure relates to a method and an apparatus for correcting inhomogeneities in the main magnetic field of an MRI scanner, a control device for an MRI system, and an MRI system.

### BACKGROUND

In MRI imaging, the spatial location and phase information of the MRI images are significantly influenced by the magnetic fields present in the imaging space. As a result, MRI images typically show imaging areas in a distorted manner when non-linear gradient fields are present. In the case of an inhomogeneous B0 field (main magnetic field), errors may occur in respect of the displayed contrast.

In medical practice, a “familiarization effect” has admittedly developed so that the images can usually be interpreted despite spatial distortions. While a spatial distortion could be computationally corrected, this usually results in unwanted image artifacts, and so the distortion is simply accepted. However, in some calculations, this distortion causes errors that are directly attributable to the distortions.

This issue is particularly relevant for water-fat separation using the Dixon method. This is based on phase unwrapping that assumes a smooth, gradually varying background phase. Since the background phase is mainly determined by the B0 field, the Dixon method fails when there are significant inhomogeneities in the main magnetic field, particularly at the margins of the imaging area.

A major challenge for compensating this effect arises when the MRI image information is distorted by non-linear gradient fields because then the information about the main magnetic field (which is undistorted) does not align with the image information (which is distorted).

### SUMMARY

An object of the aspects of the present disclosure is to provide a method and an apparatus for correcting inhomogeneities in the main magnetic field of an MRI scanner, a control device for an MRI system, and an MRI system, which overcome the above-described disadvantages.

A disclosed method is used to correct inhomogeneities in a main magnetic field of an MRI scanner. It comprises the following steps:
providing a B0 magnetic field map of the MRI scanner's main magnetic field at least within an imaging area,
providing distortion information about the behavior of gradient fields of the MRI scanner at least within the imaging area,
correcting the B0 magnetic field map or MRI images based on the distortion information by positionally aligning points in the B0 magnetic field map with pixels in MRI images within the imaging area,
outputting the corrected B0 magnetic field map or the corrected MRI images.

Inhomogeneities in a main magnetic field of an MRI scanner can be corrected in its B0 magnetic field map or in MRI images. The method covers both aspects. Ultimately, the aim is to be able to perform a Dixon method with optimum compensation for inhomogeneities in the main magnetic field.

The B0 magnetic field map can be provided in several possible ways. It is typically created by measuring the main magnetic field at many locations (at least within the imaging area) and can be made available to the method immediately after it has been created. However, it is preferable for the B0 magnetic field map to be stored in a memory area from which it can be downloaded by the method. The B0 field map of the MRI scanner's main magnetic field is usually a three-dimensional map with pixels, each indicating a magnetic field strength and preferably also the direction of the magnetic field. The B0 field (main magnetic field) should be measured very precisely when calibrating the MRI scanner. The more precise the measurement, the more accurately corrections can later be applied to the MRI images. Typically, a B0 magnetic field map is created when setting up an MRI scanner.

The distortion information is, for example, a gradient map or field information of the gradient field. This information is also usually generated during the setup of an MRI scanner. The distortion information can be a gradient map similar to the B0 magnetic field map or a function representing the behavior of the gradient field. At a minimum, it contains information about the behavior of the MRI scanner's gradient fields, at least within the imaging area.

During the correction step, the B0 magnetic field map or MRI images are corrected based on the distortion information. It should be noted that it is disadvantageous to distortion-correct the MRI images (which have been distorted by non-linearities of the gradient field) for diagnostic purposes, as such distortion-corrections can result in image artifacts. These artifacts occur, for example, because the MRI images are usually distortion-corrected slice by slice rather than incurring the additional overhead of performing a full 3D distortion correction. Moreover, a purely 2D correction is insufficient for performing certain computational further processing tasks on the images. Consequently, distorted MRI images should ultimately remain available. This can be achieved in two ways.

First, the B0 magnetic field map can be distorted to match the MRI images. Because it has been measured, it is not subject to distortions from the gradient fields. Therefore, the distortion information is used to compute a distortion function that can be applied to the B0 magnetic field map. Essentially, this involves determining, based on the distortion information, how the gradient field would distort an MRI image and deriving the corresponding distortion function therefrom. Conversely, it would be possible to determine how an MRI image would have to be distortion-corrected to represent the imaging area accurately. This “distortion correcting function” can then be inverted to obtain the distortion function with which the B0 magnetic field map has to be distorted. A B0 magnetic field map distorted in this way can be directly used to distortion-correct MRI images, as it accurately indicates, point by point, the magnetic field that was present at each pixel of a (distorted) MRI image at the time of acquisition.

However, the correction can also be applied to the pixels of MRI images. These can be distortion-corrected according to the distortion information, and then the (original) B0 magnetic field map can be used to compensate for inhomogeneities. However, the MRI images must then be distorted again to avoid image artifacts.

Basically, this means that the map points in the B0 magnetic field map are aligned with the pixels of the MRI images in respect of their positions in the imaging area.

It is preferable to correct the B0 magnetic field map, as it can then simply be stored or directly used to correct (commonly distorted) MRI images. Once stored, it can be used for a variety of MRI images or for validating separation processes since the fields will remain largely unchanged.

Once MRI images have been corrected (distortion-corrected, corrected, and then re-distorted or used in their distorted state in conjunction with a corrected B0 magnetic field map), they can be made available directly for diagnosis or used for calculations, such as those based on the Dixon method.

If a corrected B0 magnetic field map is available, MRI images can be corrected, particularly to compensate for phase shifts in complex-valued images due to inhomogeneities in the B0 magnetic field. This can be done simply by applying the information from each point of the corrected B0 magnetic field map to the corresponding point in a (distorted) MRI image. Phase correction for a complex-valued MRI image, given a known B0 magnetic field, is well known from the prior art.

An apparatus according to the disclosure is used to correct inhomogeneities in a main magnetic field of an MRI scanner. It comprises the following components:
a data interface designed to receive a B0 magnetic field map of the MRI scanner's main magnetic field and distortion information about the scanner's gradient fields at least within an imaging area,
a correction unit designed to correct the B0 magnetic field map or MRI images based on the distortion information by aligning points of the B0 magnetic field map with pixels of MRI images in respect of their positions in the imaging area,
a data interface designed to output the corrected B0 magnetic field map or the corrected MRI images.

The function of the apparatus's components has already been described above. The apparatus is preferably designed to carry out the method according to the disclosure.

If a corrected B0 magnetic field map is available, the correction unit is preferably designed to use this correction unit to correct MRI images or, more specifically, to correct phase shifts in these complex images caused by inhomogeneities in the B0 magnetic field. This can be done simply by applying the information from each point of the corrected B0 magnetic field map to each corresponding point in a (distorted) MRI image.

A disclosed control device for an MRI system comprises an apparatus according to the disclosure and/or is designed to carry out the method according to the disclosure.

An MRI system, according to the disclosure, comprises a control device according to the disclosure.

The aspects of the disclosure can be implemented in particular in the form of a computer unit running appropriate software. For this purpose, the computer unit may include, for example, one or more cooperating microprocessors or the like. In particular, it can be realized in the form of suitable software program sections in the computer unit. The advantage of a largely software-based implementation is that existing computer units can be easily upgraded via a software or firmware update to operate in the disclosed manner. Therefore, the object is also achieved by a corresponding computer program product comprising a computer program that can be directly loaded into a computer unit's memory, said program comprising sections for carrying out all the steps of the method according to the disclosure when the program is run on the computer unit. In addition to the computer program, such a computer program product may also include additional components, such as documentation and/or additional hardware components, such as hardware keys (dongles, etc.) for using the software.

For transfer to the computer unit and/or storage on or in the computer unit, a computer-readable medium, such as a memory stick, hard drive, or other portable or built-in data carrier, can be used to store the program sections of the computer program in a form readable and executable by a computer unit.

Further particularly advantageous aspects and developments of the disclosure will emerge from the dependent claims and the following description, wherein the claims of one claim category can also be developed analogously to the claims and sections of the description for another claim category and, in particular, individual features of different aspects or variants can be combined to form new aspects or variants.

According to a preferred aspect of the method, the B0 magnetic field map (with its magnetic field values) is corrected by determining, based on the distortion information, the distortion of an MRI image by the gradient field, and applying this distortion to the B0 magnetic field map. Preferably, an inverse correction of the distortions in MRI images caused by inhomogeneities in the gradient fields is applied to the B0 magnetic field map to correct it.

The distortion information about the gradient fields distorts MRI images so that after reconstruction, some of the voxels of these images do not appear in their actual real-world positions. As mentioned above, this is accepted in clinical practice since correcting the images would introduce artifacts that are undesirable. To correct the B0 magnetic field map, it is therefore necessary to determine the location to which the gradient field would shift the voxels of an MRI image and to apply that shift to the B0 magnetic field map so that the corresponding map point can be shifted to align with the pixel. Alternatively, a “distortion-correcting function” can be computed that indicates how the points of an MRI image would have to be shifted in order to be positioned correctly in the imaging area. This distortion-correcting function can be inverted to produce a distortion function as part of an inverse correction, and this distortion function can then be used to correct the B0 magnetic field map.

As a result, the points in the corrected B0 magnetic field map no longer correspond to their actual locations within the scanner tunnel (i.e., in the imaging area) but rather to locations where the corresponding points of the scanner tunnel (i.e., of the imaging area) appear in an MRI image. Thus, the B0 magnetic field map is artificially distorted to match the MRI images. In short, this correction distorts the B0 magnetic field map in the same way that MRI images are distorted by the gradient field.

The B0 magnetic field map is preferably three-dimensional. This three-dimensional B0 magnetic field map is then preferably corrected in all three spatial directions.

If a corrected B0 magnetic field map is available, the method includes the additional step of:
correcting MRI images using the corrected B0 magnetic field map, wherein a correction of the phases of the pixels of the MRI images is performed on a pixel-by-pixel basis, depending on the values of the corresponding map points in the B0 magnetic field map. The phase modulation can be calculated and demodulated, in particular, from the sequence or protocol settings. It should be noted here that the MRI images exist in a complex domain.

Preferably, the phase correction of the pixels of the MRI images is additionally corrected using an echo time associated with the image (or the duration of the dephasing). This echo time TE is to be understood here as a protocol setting. The echo time is the time interval between the excitation pulse and the readout. The signal can dephase during this time. The dephasing frequency is the Larmor frequency L multiplied by the B0 deviation B. The phase P to be demodulated is, therefore, P=L·B·TE.

The method preferably includes the additional step of:
further processing of the corrected MRI images, preferably wherein two MRI images of the same subject are combined mathematically, preferably wherein water-fat separation is performed using the Dixon method.

The further processing can basically be carried out using any known methods. For example, image values can be added, subtracted, or divided. It is important that this is done using the corrected MRI images, as the effect of inhomogeneities in the B=−magnetic field has been compensated for in these images.

The further processing can also include segmentation or automated detection of image content. For example, connected regions in the MRI images can be determined using a region growing technique.

Preferably, the images are subdivided, using the B0 magnetic field map, into a normal region with little fluctuation in the main magnetic field and a problem region with high fluctuation in the main magnetic field. Further processing can then preferably be performed differently in these two regions. Preferably, a first algorithm is used for further processing in the normal region and a second algorithm in the problem region. For example, conventional phase unwrapping is reliable in the normal region, allowing a conventional algorithm to be applied there. In the problem region, however, this algorithm could fail, requiring a different algorithm for further processing. Note that the normal region and problem region of the corrected and normal B0 magnetic field maps may differ significantly.

In the case of further processing based on a region growing technique, an algorithm is preferably applied from the normal region into the problem region, and a probability of correctness of the results is derived at least from the B0 magnetic field map. For a region growing technique of this kind, the correctness of results in the normal region is high. If this region growing technique proceeds from the normal region into the problem region, the correctness gradually decreases. Correctness can now be evaluated for each step of the region growing technique in the problem region, and if it falls below a predefined value, a boundary can be set for the region growing process (and the direction can be changed accordingly).

According to a preferred aspect of the method, the correction is performed for each map point (pixel/voxel) of the B0 magnetic field map, at least within the problem region.

In one aspect of the method, it is preferred that system-specific off-center frequencies of spherical harmonics of the main magnetic field are determined, and the expected phase values for each acquired contrast, in particular the echo time, are determined therefrom. Such frequencies result from modulation with 2π. For each region deviating by one rotation relative to the Larmor frequency for the given echo time, there is a wave. The waves become increasingly frequent because the B0 field diverges very strongly. To the point where the signal disappears due to intravoxel dephasing.

A preferred apparatus is characterized in that the correction unit is designed to correct the B0 magnetic field map by determining the distortion of an MRI image by the gradient field based on the distortion information and to apply this distortion to the B0 magnetic field map. It is preferred that the correction unit is designed to perform an inverse correction of the distortions in MRI images caused by inhomogeneities of the gradient fields in the B0 magnetic field map.

The use of AI-based methods (AI: “artificial intelligence”) is preferred for the method, according to the disclosure. Artificial intelligence is based on the principle of machine learning and is typically implemented using an appropriately trainable algorithm. The term “machine learning” is often used for this approach, which also encompasses the “deep learning” principle.

Components of the aspects of the disclosure are preferably provided as a “cloud service”. Such a cloud service is used to process data, particularly by means of artificial intelligence, but may also be a service based on conventional algorithms or a service where human analysis takes place in the background. Generally speaking, a cloud service (hereinafter also referred to as a “cloud”) is an IT infrastructure that provides storage space, computing power, and/or application software via a network. Communication between the user and the cloud is conducted via data interfaces and/or data transmission protocols. In the present case, it is particularly preferred that the cloud service provides both computing power and application software.

As part of a preferred method, data obtained according to the disclosure is provided to the cloud service via the network. This service includes a computing system that does not usually include the user's local computer. The method can thus be implemented using a command configuration in a network. The data computed in the cloud is later sent back to the user's local computer via the network.

### DESCRIPTION OF THE DRAWINGS

The aspects of the disclosure will now be explained in more detail with reference to the accompanying figures using exemplary aspects. Identical components are provided with the same reference numerals in the different figures. The figures are generally not to scale.

FIG. 1 schematically illustrates a magnetic resonance imaging system with an apparatus according to an exemplary aspect of the disclosure,

FIG. 2 shows an example of a B0 magnetic field map,

FIG. 3 shows an example of the field behavior of a gradient field,

FIG. 4 shows how the corrected B0 magnetic field map is created,

FIG. 5 shows the result of the method according to the disclosure in the form of an image comparison, and

FIG. 6 shows a block diagram of an example of the method according to the disclosure.

### DETAILED DESCRIPTION

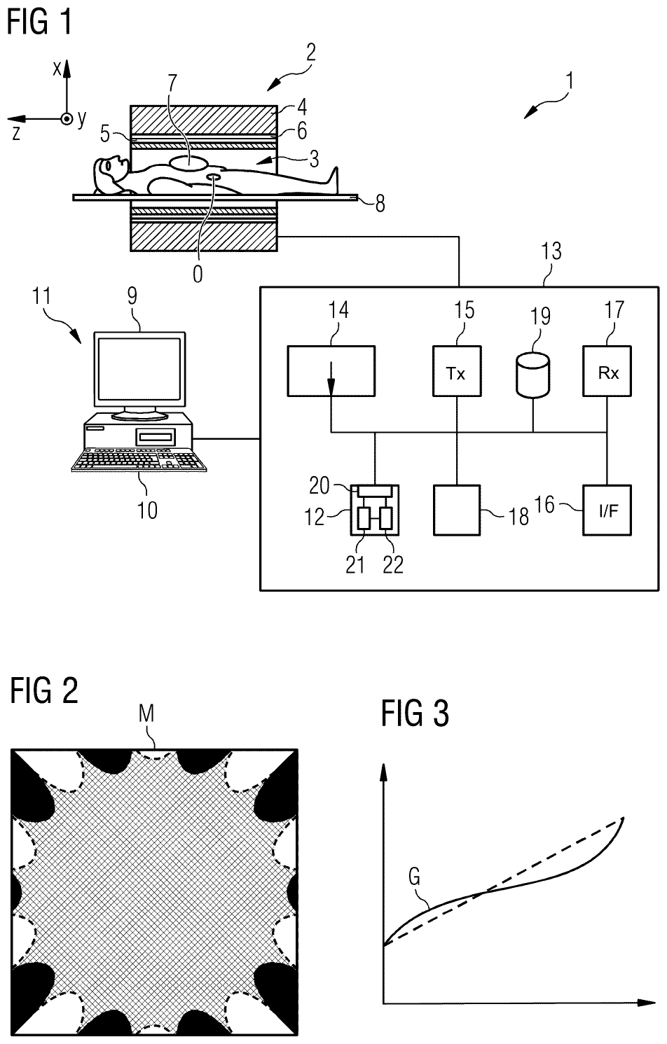

FIG. 1 shows a highly schematic representation of a magnetic resonance imaging system 1. It includes, on the one hand, the actual magnetic resonance scanner 2 with an examination space 3 or patient tunnel (referred to here as the imaging area 3), in which a patient or test subject is positioned on a table 8, with the actual object under examination O located inside their body.

The magnetic resonance scanner 2 is conventionally equipped with a main magnetic field system 4, a gradient system 6, an RF transmit antenna system 5, and an RF receive antenna system 7. In the exemplary aspect shown, the RF transmit antenna system 5 is a whole-body coil permanently installed in the MRI scanner 2, while the RF receive antenna system 7 consists of local coils to be placed on the patient or test subject (symbolized here by a single local coil). However, the whole-body coil can basically also be used as an RF receive antenna system and the local coils can be used as an RF transmit antenna system, provided that these coils can each be switched between different operating modes. The main magnetic field system 4 is conventionally designed to generate a main magnetic field along the longitudinal axis of the patient, i.e., in the z-direction along the longitudinal axis of the magnetic resonance scanner 2. The gradient system 6 typically includes individually controllable gradient coils in order to be able to switch gradients in the x-, y- or z-direction independently of each other.

The magnetic resonance imaging system shown here is a whole-body system with a patient tunnel into which a patient can be fully inserted. In principle, however, the aspects of the disclosure can also be applied to other magnetic resonance imaging systems, e.g., with a C-shaped housing that is open to the side. The key requirement is that corresponding images of the object under examination O can be acquired.

The magnetic resonance imaging system 1 further comprises a central control device 13, which is used to control the MR system 1. This central control device 13 includes a sequence control unit 14. This unit controls the sequence of radiofrequency (RF) pulses and gradient pulses depending on a selected pulse sequence or a succession of multiple pulse sequences for acquiring multiple slices in the imaging area within a measurement session. Such a pulse sequence can, for example, be predefined and parameterized within a measurement or control protocol. Typically, various control protocols for different measurements or measurement sessions are stored in a memory 19 and can be selected (and, if necessary, modified) by an operator and then used to perform the measurement.

The examination region can be defined on the basis of selected pulse sequences or based on the positioning of the aforementioned RF receive antenna system 7.

To output the individual RF pulses of a pulse sequence, the central control device 13 has a radiofrequency transmit device 15 that generates and amplifies the RF pulses and feeds them via a suitable interface (not shown in detail) into the RF transmit antenna system 5. The control device 13 has a gradient system interface 16 for controlling the gradient coils of the gradient system 6 in order to switch the gradient pulses appropriately according to the predefined pulse sequence. The diffusion gradient pulses and spoiler gradient pulses could be applied via said gradient system interface 16. By sending sequence control data, for example, the sequence control unit 14 communicates in a suitable manner with the radiofrequency transmit device 15 and the gradient system interface 16 to execute the pulse sequence.

The control device 13 also comprises a radiofrequency receive device 17 (which likewise communicates in a suitable manner with the sequence control unit 14) in order to receive, by means of the RF receive antenna system 7, magnetic resonance signals in a coordinated manner within the readout windows defined by the pulse sequence and thus acquire the raw data.

A reconstruction unit 18 takes the acquired raw data and reconstructs magnetic resonance image data from it. This reconstruction is also typically based on parameters that may be predefined in the respective measurement or control protocol. This image data can then be stored in a memory 19, for example.

The process whereby suitable raw data is acquired through RF pulse irradiation and the switching of gradient pulses and how MRI images or parameter maps are reconstructed therefrom is generally well-known to persons skilled in the art and will not, therefore, be explained in more detail here.

The control device 13 further includes a disclosed apparatus 12 for correcting inhomogeneities in a main magnetic field of an MRI scanner. The apparatus 12 comprises a data interface 20 and a correction unit 22.

The data interface 20 is used to receive a B0 magnetic field map M of the main magnetic field of the MRI scanner and distortion information G for gradient fields of the MRI scanner at least within an imaging area.

The correction unit 22 is used to correct the B0 magnetic field map M or MRI images B based on the distortion information G by aligning map points K of the B0 magnetic field map M (and associated magnetic field values) with pixels of MRI images B in respect of their positions in the imaging area. In the example shown here, the correction unit 22 is designed solely to correct the B0 magnetic field map M by determining the distortion of an MRI image B due to the gradient field based on the distortion information G, and applying this distortion to the B0 magnetic field map M.

The data interface 20 is also used to output the corrected B0 magnetic field map M.

The central control device 13 can be operated via a terminal 11 comprising an input unit 10 and a display unit 9, from which a single operator can also control the entire magnetic resonance imaging system 1. MRI images can also be displayed on the display unit 9, and the input unit 10, optionally in combination with the display unit 9, can be used to plan and start measurements and, in particular, to select and, if necessary, modify control protocols.

The disclosed magnetic resonance imaging system 1, and in particular the control device 13, may also comprise numerous other components (not shown in detail here but commonly present in such systems), such as a network interface for connecting the entire system to a network and exchanging raw data and/or image data or parameter maps, as well as other data, such as patient-related data or control protocols.

How suitable raw data can be acquired by irradiating with RF pulses and generating gradient fields and how magnetic resonance imaging images can be reconstructed from this data is generally known to those skilled in the art and will not be explained in detail here.

FIG. 2 shows a B0 magnetic field map M typically obtained by measuring the B0 magnetic field using known methods. A comparatively homogeneous area is visible in the center, surrounded by inhomogeneities. Normal values for the main magnetic field are indicated by gray shading, excessively high values in black, and excessively low values in white. The deviations are in the ppm range. It should be noted that this is merely a schematic representation. In reality, the transitions between the illustrated areas are continuous.

It should be noted that, as a rule, the B0 magnetic field maps M are three-dimensional and ideally represent the magnetic field throughout the three-dimensional imaging area 3.

FIG. 3 shows an example of a gradient field behavior in the form of a gradient map G. Ideally, the behavior is strictly linear, as indicated by the dashed line. In reality, however, the behavior deviates from this linearity (solid line), resulting in image distortions.

It should also be noted here that the gradient maps G are generally three-dimensional and ideally represent the gradient field throughout the entire three-dimensional imaging area 3.

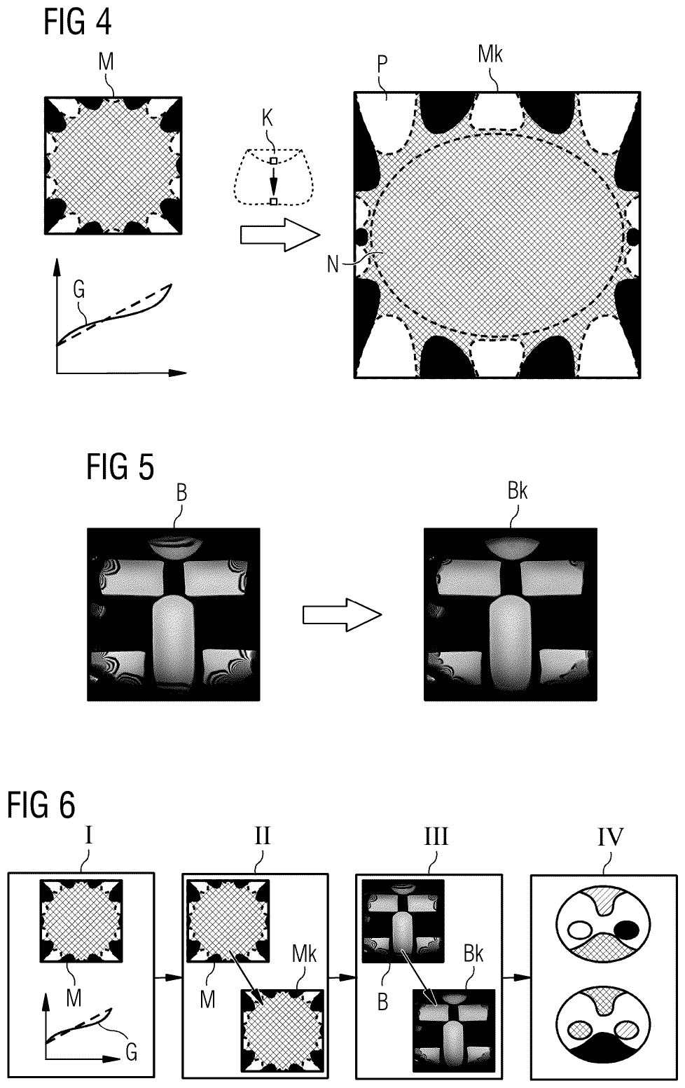

FIG. 4 depicts the creation of a corrected B0 magnetic field map Mk. On the left, the B0 magnetic field map M from FIG. 2 and the gradient map G from FIG. 4 are shown, these forming the basis in this example. First, it is determined how a pixel of an MRI image would be distorted by the gradient field G. For this purpose, it can be calculated, for example, where a point in the imaging area 3 would be mapped in an MRI image due to the deviation of the gradient field G from linearity, and from this a distortion function can be determined. This distortion function is then used to distort the B0 magnetic field map. This is indicated by the distortion of the upper white edge area of the B0 magnetic field map.

This creates the corrected B0 magnetic field map Mk. The pixels of the corrected B0 magnetic field map Mk represent magnetic field strengths and are located at the points where the corresponding field strengths would also have an effect in the (distorted) MRI images B. Essentially, the magnetic field has been distorted in the same way as the imaging area 3 is distorted in the MRI images B, so that these MRI images B can be directly corrected using the corrected B0 magnetic field map Mk.

In the corrected B0 magnetic field map Mk, the normal region N is separated from the problem region P by a dashed circular line. In the normal region N, B-field inhomogeneities can be disregarded, but not in the problem region P.

FIG. 5 shows the result in a corrected MRI image Bk (right) in which inhomogeneities have been compensated for using the corrected B0 magnetic field map Mk, compared to a conventional MRI image B (left) in which inhomogeneities have been compensated for using the original B0 magnetic field map M. In the edge area, i.e., where there are large inhomogeneities in the B0 magnetic field, the corrected MRI image B shows significantly fewer circular stripe structures than the conventional MRI image. These structures arise from incorrectly compensated inhomogeneities.

FIG. 6 shows a block diagram of an example of a disclosed method for correcting inhomogeneities of a main magnetic field of an MRI scanner 2.

In step I, a B0 magnetic field map M of the main magnetic field of the MRI scanner 1 is provided, e.g. by measuring the magnetic field at many positions in the imaging area 3 or by downloading a B0 magnetic field map M that has already been created. The B0 field (main magnetic field) should be measured very precisely when calibrating the MRI scanner 1.

Additionally provided in step I is distortion information G, e.g., in the form of a gradient map G or its field information. This distortion information G contains information about the behavior of gradient fields of the MRI scanner 2 at least in the imaging area 3.

In step II, the provided B0 magnetic field map Mis corrected based on the distortion information G. This is done by determining the distortion of an MRI image B by the gradient field based on the distortion information G, and applying this distortion to the B0 magnetic field map M. This brings map points K of the B0 magnetic field map M and pixels of MRI images B into alignment in respect of their positions in the imaging area 3.

In step III, MRI images B are corrected using the corrected B0 magnetic field map M. The corrected MRI images Bk can then be combined mathematically, e.g., using a Dixon method.

In step IV, two outputs are generated using the Dixon method from two corrected MRI images Bk. Because the corrected MRI images have better compensation for inhomogeneities of the main magnetic field at the edges, the Dixon method is more successful than with conventional MRI images.

Finally, it should be noted once again that the aspects of the disclosure described in detail above merely recites exemplary aspects, which can be modified by persons skilled in the art in a variety of ways without departing from the scope of the disclosure. Furthermore, the use of the indefinite article “a” or “an” does not preclude the possibility that the features in question may be present more than once. Likewise, terms such as “unit” do not exclude the possibility that the components in question consist of several interacting sub-components, which may also be spatially distributed. The term “a number” is to be read as “at least one”. Independent of the grammatical term usage, individuals with male, female, or other gender identities are included within the term.

1. A method for correcting inhomogeneities of a main magnetic field of an MRI scanner, comprising:
providing a B0 magnetic field map of the main magnetic field of the MRI scanner at least in an imaging area;
providing distortion information about a behavior of gradient fields of the MRI scanner at least in the imaging area;
correcting the B0 magnetic field map or MRI images based on the distortion information by bringing map points of the B0 magnetic field map and pixels of MRI images into alignment with respect to their positions in the imaging area; and
outputting the corrected B0 magnetic field map or the corrected MRI images.

2. The method as claimed in claim 1, further comprising:
correcting the B0 magnetic field map by determining, based on the distortion information, the distortion of an MRI image by the gradient field, and applying this distortion to the B0 magnetic field map.

3. The method as claimed in claim 2, wherein to correct the B0 magnetic field map, the method further comprising performing in the B0 magnetic field map an inverse correction of the distortions in MRI images caused by inhomogeneities of the gradient fields.

4. The method as claimed in claim 1, wherein the B0 magnetic field map is three-dimensional and the B0 magnetic field map is corrected in all three spatial directions.

5. The method as claimed in claim 1, further comprising:
correcting MRI images using the corrected B0 magnetic field map, wherein phase correction of the pixels of the MRI images is performed on a pixel-by-pixel basis depending on the values of corresponding map points in the B0 magnetic field map and preferably also in accordance with an echo time assigned to an MRI image.

6. The method as claimed in claim 5, further comprising:
further processing the corrected MRI images.

7. The method as claimed in claim 6, wherein two corrected MRI images having the same subject are combined mathematically.

8. The method as claimed in claim 7, wherein a separation of fat and water is performed using the Dixon method.

9. The method as claimed in claim 5, wherein the corrected MRI images are subdivided into a normal region of low fluctuation of the main magnetic field and a problem region of high fluctuation of the main magnetic field using the B0 magnetic field map, the further processing being performed differently in the two regions, wherein a first algorithm is used for further processing in the normal region and a second algorithm is used for further processing in the problem region.

10. The method as claimed in claim 9, wherein, during the further processing, the method further comprises:
applying a region growing algorithm from the normal region into the problem region; and
deriving a probability for the correctness of results at least from the B0 magnetic field map.

11. The method as claimed in claim 9, wherein the correction is performed for each map point of the B0 magnetic field map at least in the problem region.

12. The method as claimed in claim 1, further comprising:
determining system-specific off-center frequencies of spherical harmonics of the main magnetic field; and
determining, from the system-specific off-center frequencies, expected values for phases for each acquired contrast.

13. An apparatus for correcting inhomogeneities of a main magnetic field of an MRI scanner, comprising:
a data interface designed to receive a B0 magnetic field map of the main magnetic field of the MRI scanner and distortion information of gradient fields of the MRI scanner at least in an imaging area;
a correction unit designed to correct, based on the distortion information, the B0 magnetic field map or MRI images by aligning map points of the B0 magnetic field map and pixels of MRI images) with respect to their positions in the imaging area; and
a data interface designed to output the corrected B0 magnetic field map or the corrected MRI images.

14. The apparatus as claimed in claim 13, wherein the correction unit is designed to correct the B0 magnetic field map by determining, based on the distortion information, the distortion of an MRI image by the gradient field and applying this distortion to the B0 magnetic field map.

15. The apparatus as claimed in claim 14, wherein the correction unit is designed to perform an inverse correction of the distortions in MRI images due to inhomogeneities of the gradient fields in the B0 magnetic field map.

16. A control device for an MRI system, comprising an apparatus according to claim 13.

17. An MRI system comprising a control device as claimed in claim 16.

18. A non-transitory computer-readable storage medium comprising instructions which, when executed by a computer, cause the computer to carry out the steps of the method as claimed in claim 1.
